(19) United States
(12) Patent Application Publication
(10) Pub. No.: US 2025/0054748 A1
(43) Pub. Date: Feb. 13, 2025

(54) ADHESION IMPROVEMENTS IN METAL-CONTAINING HARDMASKS

(71) Applicant: Applied Materials, Inc., Santa Clara, CA (US)

(72) Inventors: Guangyan Zhong, Sunnyvale, CA (US); Jongbeom Seo, San Jose, CA (US); Eswaranand Venkatasubramanian, Santa Clara, CA (US); Abhijit Basu Mallick, Fremont, CA (US)

(73) Assignee: Applied Materials, Inc., Santa Clara, CA (US)

(21) Appl. No.: 18/232,133

(22) Filed: Aug. 9, 2023

(51) Int. Cl. H01L 21/02; C23C 16/02; C23C 16/50; H01J 37/32; H01L 21/285

(52) U.S. Cl. CPC H01L 21/02274; C23C 16/0272; C23C 16/50; H01J 37/32449; H01L 21/02175; H01L 21/02181; H01L 21/02183; H01L 21/02186; H01L 21/02189; H01L 21/022; H01L 21/28568; H01J 37/32522; H01J 2237/2001; H01J 2237/332

(57) ABSTRACT

Exemplary methods of semiconductor processing may include providing a treatment precursor to a processing region of a semiconductor processing chamber. A substrate may be disposed within the processing region. The methods may include contacting a surface of the substrate with the treatment precursor. The methods may include providing deposition precursors to the processing region. The deposition precursors may include a metal-containing precursor. The methods may include forming plasma effluents of the deposition precursors. The methods may include contacting the substrate with the plasma effluents of the deposition precursors. The contacting may deposit a metal-containing hardmask on the substrate.

### TECHNICAL FIELD

The present technology relates to methods and components for semiconductor processing. More specifically, the present technology relates to systems and methods for producing hardmask materials.

### BACKGROUND

Integrated circuits are made possible by processes which produce intricately patterned material layers on substrate surfaces. Producing patterned material on a substrate requires controlled methods for forming and removing material. As device sizes continue to reduce, aspect ratios of structures may grow, and maintaining dimensions of these structures during removal operations may be challenged. To facilitate patterning of materials on a substrate, hardmask material may be employed. As the number of material layers being patterned is expanding, hardmask selectivity to multiple materials is becoming a greater challenge. Additionally, as device sizes continue to reduce, adhesion between different materials is also becoming a greater challenge.

Thus, there is a need for improved systems and methods that can be used to produce high quality devices and structures. These and other needs are addressed by the present technology.

### SUMMARY

Exemplary methods of semiconductor processing may include providing a treatment precursor to a processing region of a semiconductor processing chamber. A substrate may be disposed within the processing region. The methods may include contacting a surface of the substrate with the treatment precursor. The methods may include providing deposition precursors to the processing region. The deposition precursors may include a metal-containing precursor. The methods may include forming plasma effluents of the deposition precursors. The methods may include contacting the substrate with the plasma effluents of the deposition precursors. The contacting may deposit a metal-containing hardmask on the substrate.

In some embodiments, the treatment precursor may be or include a hydrogen-containing precursor, a nitrogen-containing precursor, or a hydrogen-and-nitrogen-containing precursor. The methods may include forming plasma effluents of the treatment precursor. The plasma effluents of the treatment precursor may be formed at a plasma power of less than or about 1,000 W. The methods may include, prior to providing the deposition precursors, providing a seed layer precursor to the processing region, and contacting the substrate with the seed layer precursor. The contacting may deposit a seed layer on the substrate. The metal-containing hardmask may be deposited on the seed layer. The seed layer precursor may include one or more of a boron-containing precursor, a nitrogen-containing precursor, and a silicon-containing precursor. The methods may include forming plasma effluents of the seed layer precursor. The metal-containing hardmask may include one or more of chromium, cobalt, hafnium, molybdenum, osmium, ruthenium, rhenium, tantalum, titanium, tungsten, and zirconium.

Some embodiments of the present technology encompass semiconductor processing methods. The methods may include providing a seed layer precursor to a processing region of a semiconductor processing chamber. A substrate may be disposed within the processing region. The methods may include contacting the substrate with the seed layer precursor. The contacting may deposit a seed layer on the substrate. The methods may include providing deposition precursors to the processing region. The deposition precursors may include a metal-containing precursor. The methods may include forming plasma effluents of the deposition precursors. The methods may include contacting the substrate with the plasma effluents of the deposition precursors. The contacting may deposit a metal-containing hardmask on the substrate.

In some embodiments, the seed layer may consist of boron, nitrogen, oxygen, silicon, or a combination thereof. The methods may include forming plasma effluents of the seed layer precursor. The plasma effluents of the seed layer precursor may be formed at a plasma power of less than or about 2,000 W. The substrate may include a layer of silicon-containing material or a layer of carbon-containing material. The methods may include increasing a flow rate of the metal-containing precursor while contacting the substrate with the plasma effluents of the deposition precursors, increasing a plasma power while contacting the substrate with the plasma effluents of the deposition precursors, or both.

Some embodiments of the present technology encompass semiconductor processing methods. The methods may include providing deposition precursors to a processing region of a semiconductor processing chamber. A substrate may be disposed within the processing region. The deposition precursors may include a metal-containing precursor. The methods may include forming plasma effluents of the deposition precursors. The methods may include contacting the substrate with the plasma effluents of the deposition precursors. The contacting may deposit a metal-containing hardmask on the substrate. A flow rate of at least one of the deposition precursors, a plasma power, or both may be increased during a first amount of deposition of the metal-containing hardmask.

In some embodiments, the methods may include, prior to providing the deposition precursors, contacting a surface of the substrate with a treatment precursor, contacting the surface of the substrate with a seed layer precursor, or both. Contacting the surface of the substrate with the seed layer precursor may deposit a seed layer on the substrate. The first amount of deposition may be less than or about 10% of a total deposition duration. The metal-containing precursor may be or include a chromium-containing precursor, a cobalt-containing precursor, a hafnium-containing precursor, a molybdenum-containing precursor, an osmium-containing precursor, a ruthenium-containing precursor, a rhenium-containing precursor, a tantalum-containing precursor, a titanium-containing precursor, a tungsten-containing precursor, or a zirconium-containing precursor. The deposition precursors may further include one or more of a boron-containing precursor, a nitrogen-containing precursor, and a silicon-containing precursor. A temperature in the processing region may be maintained at less than or about 600° C.

Such technology may provide numerous benefits over conventional systems and techniques. For example, embodiments of the present technology may produce hardmask materials that may better adhere to underlayers and/or overlayers. Additionally, the present technology may reduce peeling of formed hardmask materials during subsequent processing. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary plasma system according to some embodiments of the present technology.

FIG. 2 show operations in a semiconductor processing method according to some embodiments of the present technology.

FIGS. 3A-3D show cross-sectional views of substrates being processed according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Hardmask films are utilized for a number of processing operations, which may include forming patterns through multiple layers of different materials. Increasing etch selectivity of these materials relative to the hardmask film affords tighter control of critical dimensions, especially as feature sizes continue to shrink. Amorphous silicon or carbon films are often employed as hardmasks, although selectivity for these films is becoming a greater challenge for more complex memory and logic structures, which may have multiple different films on a substrate, and which may require patterning into high aspect ratio features. Accordingly, newer films may include the incorporation of metal materials within the film to increase etch selectivity. As one non-limiting example, tungsten may be incorporated with a carbon film to increase selectivity relative to a number of oxide and nitride materials. However, as tungsten incorporation within the film is increased, a number of issues may develop.

Tungsten, and other metal-containing materials, may be deposited using metal-halide precursors. In the case of tungsten, tungsten hexafluoride may be used in deposition in a plasma-enhanced chemical vapor deposition process. During the plasma deposition, residual fluorine may be incorporated within the crystalline structure, and may diffuse through the film to the hardmask interface with the substrate. This may reduce adhesion of the film, which may cause undercut during subsequent etching, and may cause film peeling and device failure. To limit adhesion issues, many conventional technologies may utilize hydrogen during the deposition process, which may accept residual fluorine and withdraw it from the chamber as a volatile byproduct.

Incorporating hydrogen into the film may cause additional issues during processing. For example, hydrogen incorporated in the film may be less thermally stable, and during later processing outgassing may occur. Additionally, hydrogen may affect film stress, which may cause the film to become increasingly compressive, which can cause film delamination as well. Finally, volumes of hydrogen within the plasma may affect the deposition process, and may cause increased grain size and crystallinity of the formed tungsten and carbon film. For example, conventional processes may be characterized by grain sizes of 2 nm or more. As critical dimensions reduce to 20 nm or less, these grain sizes may increase surface roughness, and may increase line-edge roughness and line-width roughness during etching operations. Additionally, the larger grain structure may cause an effective twisting during formation of higher aspect ratio features, which may impact subsequent operations by lowering critical dimension uniformity.

To improve grain issues of films, some conventional processes take remedial action. For example, conventional techniques may reduce tungsten incorporation, perform multiple deposition operations, or incorporate boron doping. All of these changes may detrimentally impact processing. For example, as tungsten percentage is reduced, etch selectivity for the film may be reduced as well. Multiple deposition operations may increase queue times, and boron incorporation may reduce the film extinction coefficient.

The present technology overcomes these issues by performing one or more operations to increase adhesion of the metal-containing hardmask to the substrate or one or more layers formed on the substrate. The present technology may perform a surface treatment operation to introduce terminations, such as dangling bonds or ligands, on the surface. The terminations may better bond and adhere to hardmask materials. The present technology may additionally or alternatively form a seed layer that serves to better adhere to both the substrate or one or more layers formed on the substrate and the hardmask materials. Further, the present technology may additionally or alternatively perform ramping of process conditions to allow for better adherence of hardmask materials.

Although the remaining disclosure will routinely identify specific deposition processes utilizing the disclosed technology, it will be readily understood that the systems and methods are equally applicable to other deposition, etch, and cleaning chambers, as well as processes as may occur in the described chambers. Accordingly, the technology should not be considered to be so limited as for use with these specific deposition processes or chambers alone. The disclosure will discuss one possible chamber that may be used to perform processes according to embodiments of the present technology before additional variations and adjustments to this system according to embodiments of the present technology are described.

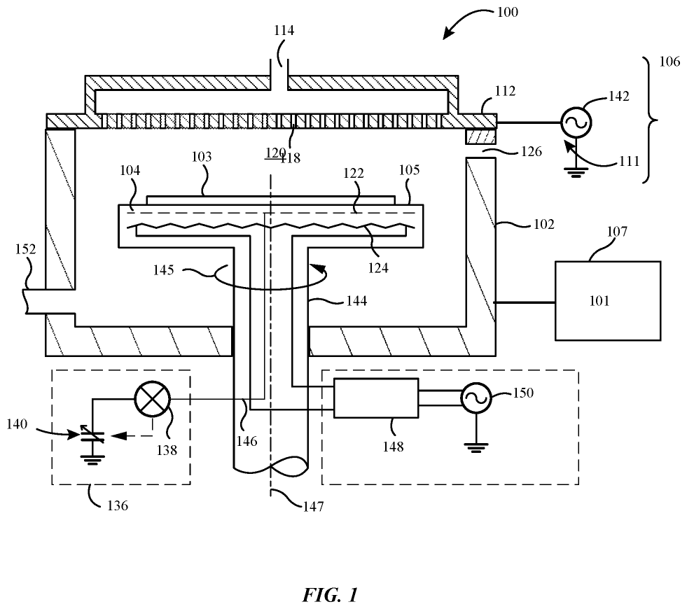

FIG. 1 shows a cross-sectional view of an exemplary processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers, etch material layers, form other material layers, or a combination thereof, although it is to be understood that deposition and etch methods may similarly be performed in any chamber within which deposition and etch processes may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. In some embodiments, the substrate support 104 may be rotatable, as indicated by the arrow 145, along an axis 147, where a shaft 144 of the substrate support 104 may be locate, or may be stationary. Alternatively, the substrate support 104 may be lifted up to rotate as necessary during a deposition process.

A gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

A first electrode 122 may be coupled with the substrate support 104. The first electrode 122 may be embedded within the substrate support 104 or coupled with a surface of the substrate support 104. The first electrode 122 may be a plate, a perforated plate, a mesh, a wire screen, or any other distributed arrangement of conductive elements. The first electrode 122 may be a tuning electrode and may be coupled with a tuning circuit 136 by a conduit 146, for example a cable having a selected resistance, such as 50 ohms, for example, disposed in the shaft 144 of the substrate support 104. The tuning circuit 136 may have an electronic sensor 138 and an electronic controller 140, which may be a variable capacitor. The electronic sensor 138 may be a voltage or current sensor and may be coupled with the second electronic controller 140 to provide further control over plasma conditions in the processing volume 120.

A second electrode 124, which may be a bias electrode and/or an electrostatic chucking electrode, may be coupled with the substrate support 104. The second electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power. The substrate support 104 may also include one or more heating elements configured to heat the substrate to a processing temperature, which may be between about 25° C. and about 800° C. or greater.

The lid assembly 106 and substrate support 104 of FIG. 1 may be used with any processing chamber for plasma or thermal processing. In operation, the processing chamber 100 may afford real-time control of plasma conditions in the processing volume 120, such as via a system controller 101 which may be contained within a processor 107. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the second electrode 124 in some embodiments.

Upon energizing a plasma in the processing volume 120, a potential difference may be established between the plasma and the first electrode 122. The electronic controller 140 may then be used to adjust the flow properties of the ground paths represented by the tuning circuit 136. A set point may be delivered to the first circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Tuning circuit 136 may have a variable impedance that may be adjusted using the electronic controller 140. Where the electronic controller 140 is a variable capacitor, the capacitance range of each of the variable capacitors, may be chosen to provide an impedance range. This range may depend on the frequency and voltage characteristics of the plasma, which may have a minimum in the capacitance range of each variable capacitor. Hence, when the capacitance of the electronic controller 140 is at a minimum or maximum, impedance of the tuning circuit 136 may be high, resulting in a plasma shape that has a minimum aerial or lateral coverage over the substrate support. When the capacitance of the electronic controller 140 approaches a value that minimizes the impedance of the tuning circuit 136, the aerial coverage of the plasma may grow to a maximum, effectively covering the entire working area of the substrate support 104. As the capacitance of the electronic controller 140 deviates from the minimum impedance setting, the plasma shape may shrink from the chamber walls and aerial coverage of the substrate support may decline.

The electronic sensor 138 may be used to tune the circuit 136 in a closed loop. A set point for current or voltage, depending on the type of sensor used, may be installed in each sensor, and the sensor may be provided with control software that determines an adjustment to the respective electronic controller 140 to minimize deviation from the set point. Consequently, a plasma shape may be selected and dynamically controlled during processing. It is to be understood that, while the foregoing discussion is based on electronic controller 140, which may be a variable capacitor, any electronic component with adjustable characteristic may be used to provide tuning circuit 136 with adjustable impedance.

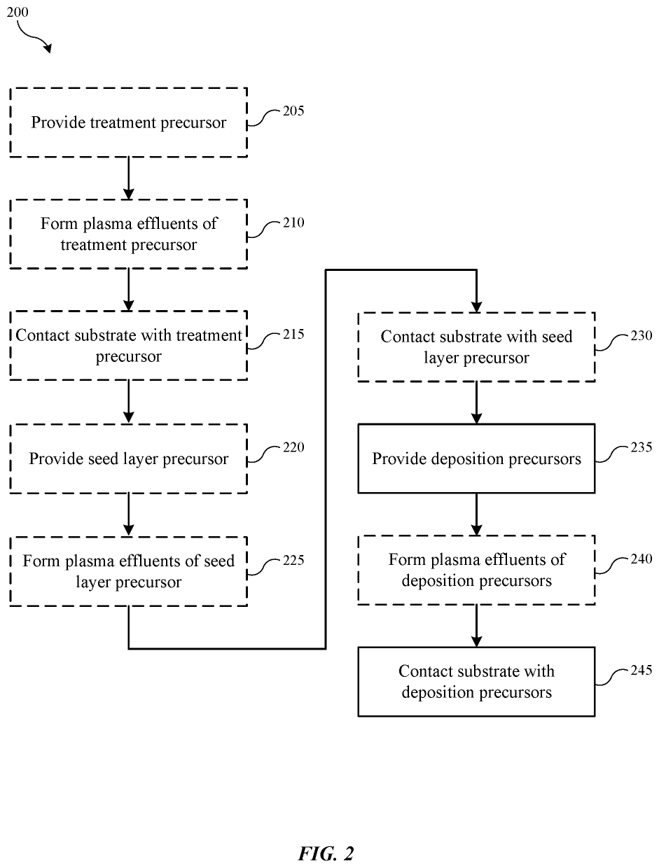

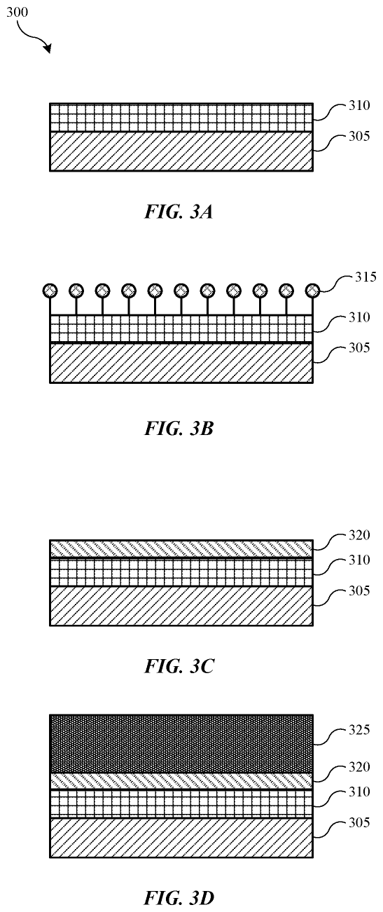

Processing chamber 100 may be utilized in some embodiments of the present technology for processing methods that may include deposition of hardmask materials for semiconductor structures. It is to be understood that the chamber described is not to be considered limiting, and any chamber that may be configured to perform operations as described may be similarly used. FIG. 2 shows exemplary operations in a processing method 200 according to some embodiments of the present technology. The method may be performed in a variety of processing chambers and on one or more mainframes or tools, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. Method 200 may describe operations shown schematically in FIGS. 3A-3D, the illustrations of which will be described in conjunction with the operations of method 200. It is to be understood that the figures illustrate only partial schematic views, and a substrate may contain any number of additional materials and features having a variety of characteristics and aspects as illustrated in the figures.

Method 200 may include additional operations prior to initiation of the listed operations. For example, additional processing operations may include forming structures or features on a substrate, which may include both forming and removing material. For example, transistor structures, memory structures, or any other structures may be formed. Prior processing operations may be performed in the chamber in which method 200 may be performed, or processing may be performed in one or more other processing chambers prior to delivering the substrate into the semiconductor processing chamber or chambers in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support, which may be a pedestal such as substrate support 104, and which may reside in a processing region of the chamber, such as processing volume 120 described above.

As illustrated in FIG. 3A, a substrate on which several operations have been performed may be substrate 305 of a structure 300, which may show a partial view of a substrate on which semiconductor processing may be performed. It is to be understood that structure 300 may show only a few top layers during processing to illustrate aspects of the present technology. The substrate 305 may include a material in which one or more materials may be formed on. Substrate 305 may be any number of materials used in semiconductor processing. In embodiments, the substrate 305 may include a layer of material 310, such as a layer of silicon-containing material or a layer of carbon-containing material. The layer of silicon-containing material may be, for example, amorphous silicon, silicon oxide, silicon nitride, silicon oxynitride, silicon carbide, silicon oxycarbide, silicon carbonitride, or any other silicon-containing material. The carbon-containing material may be, for example, amorphous carbon or any other carbon-containing material.

Optional operations 205-215 and operations 220-230 may be performed separately or in sequential combination to increase adhesion between a hardmask material and an underlayer, which may be substrate 305 or a layer of material 310 formed on the substrate 305. For example, prior to forming hardmask material, method 200 may include a surface treatment at optional operations 205-215. Additionally or alternatively, prior to forming hardmask material, method 200 may include depositing a seed layer at optional operations 220-230.

In embodiments, method 200 may include providing a treatment precursor to the processing region of the semiconductor processing chamber at optional operation 205. Plasma effluents of the treatment precursor may optionally be formed at optional operation 210. However, it is also contemplated that plasma effluents may not be formed, and a thermal treatment operation may be performed. At optional operation 215, method 200 may include contacting a surface of the substrate 305 with the treatment precursor or, if formed, the plasma effluents thereof. As illustrated in FIG. 3B, depending on the treatment precursor used, terminations 315 of material in the treatment precursor may be formed on the surface of the substrate 305. The terminations 315 formed may provide dangling bonds or other ligand terminations at the surface of the substrate 305, which may increase interaction with deposition precursors in subsequent operations.

The treatment precursor provided at optional operation 205 may be a hydrogen-containing precursor, a nitrogen-containing precursor, or a hydrogen-and-nitrogen-containing precursor. An exemplary hydrogen-containing precursor may be diatomic hydrogen (H₂). An exemplary nitrogen-containing precursor may be diatomic nitrogen (N₂). An exemplary hydrogen-and-nitrogen-containing-containing precursor may be ammonia (NH₃). Any other hydrogen-containing precursor, a nitrogen-containing precursor, or a hydrogen-and-nitrogen-containing precursor used or useful in semiconductor processing may additionally or alternatively be provided to introduce dangling bonds or other ligand terminations on the surface of the substrate 305. One or more carrier or inert gases may be provided to the processing region with the treatment precursor. For example, argon, helium, xenon, or any other inert gas may be provided with the treatment precursor.

The plasma effluents of the treatment precursor may be formed at a plasma power of less than or about 1,000 W, and may be formed at less than or about 900 W, less than or about 800 W, less than or about 750 W, less than or about 700 W, less than or about 650 W, less than or about 600 W, less than or about 550 W, less than or about 500 W, or less. Higher plasma powers, such as greater than 1,000 W, may begin to damage a surface of the substrate 305 due to bombardment by the treatment precursor. Additionally, lower plasma powers, such as less than or about 100 W, may not successfully ionize the treatment precursor and, therefore, dangling bonds or other ligand terminations may not be introduced on the surface of the substrate 305. Accordingly, the plasma effluents of the treatment precursor may be formed at a plasma power of between about 500 W and about 1,000 W, or between any other range of the values previously stated.

After a period of treatment at optional operation 215, method 200 may include depositing the seed layer at optional operations 220-235. Method 200 may include providing a seed layer precursor or multiple seed layer precursors to the processing region of the semiconductor processing chamber at optional operation 220. Plasma effluents of the seed layer precursor(s) may optionally be formed at optional operation 225. However, it is also contemplated that plasma effluents may not be formed, and a thermal seed layer deposition may be performed. At optional operation 230, method 200 may include contacting the surface of the substrate 305 with the seed layer precursor(s) or, if formed, the plasma effluents thereof. As illustrated in FIG. 3C, seed layer 320 may be deposited on the surface of the substrate 305 at operation 230. The seed layer 320 may provide a transition between the substrate 305 or layer of material 310 on the substrate 305 and the hardmask material as further discussed below.

The seed layer precursor provided at optional operation 220 may include one or more of a boron-containing precursor, a nitrogen-containing precursor, and a silicon-containing precursor. An exemplary boron-containing precursor may be diborane (B₂H₆). Exemplary nitrogen-containing precursors may be ammonia (NH₃) or nitrous oxide (N₂O). Exemplary silicon-containing-containing precursors may be silane (SiH₄) or disilane (Si₂H₆). Any other boron-containing precursor, nitrogen-containing precursor, and silicon-containing precursor used or useful in semiconductor processing may additionally or alternatively be provided to deposit the seed layer 320 on the surface of the substrate 305. Similar to the treatment precursor, one or more carrier or inert gases may be provided to the processing region with the seed layer precursor. For example, argon, helium, xenon, or any other inert gas may be provided with the seed layer precursor.

In embodiments, the seed layer precursor(s) may not include any other material than boron, hydrogen, nitrogen, oxygen, and/or silicon. Accordingly, the seed layer 320 may be greater than or about 90 at. % boron, nitrogen, oxygen, and silicon, and may be greater than or about 95 at. %, greater than or about 97 at. %, greater than or about 99 at. %, greater than or about 99.9 at. %, or consist entirely of boron, hydrogen, nitrogen, oxygen, and/or silicon.

The plasma effluents of the seed layer precursor may be formed at a plasma power of less than or about 2,250 W, and may be formed at less than or about 2,000 W, less than or about 1,750 W, less than or about 1,500 W, less than or about 1,250 W, less than or about 1,000 W, less than or about 750 W, less than or about 500 W, less than or about 250 W, or less. Higher plasma powers may increase deposition rate of the seed layer 320 whereas lower plasma powers may decrease deposition rate of the seed layer 320. Similarly, higher plasma powers may increase bombardment and densify the seed layer 320 during deposition. Conversely, lower plasma powers may reduce bombardment and deposit a poorer quality seed layer 320. However, too high of a plasma power may make it difficult to control a thickness of the seed layer 320. Accordingly, the plasma effluents of the seed layer precursor may be formed at a plasma power of between about 250 W and about 2,250 W, or between any other range of the values previously stated.

Depending on the seed layer precursors used, the seed layer 320 may be a boron-containing material, such as amorphous boron, or a silicon-containing material, such as amorphous silicon. Optional operation 230 may be continued for a sufficient amount of time to form the seed layer 320 to a desired thickness. In embodiments, a thickness of the seed layer 320 may be less than or about 500 Å, and may be less than or about 400 Å, less than or about 300 Å, less than or about 200 Å, less than or about 100 Å, less than or about 80 Å, less than or about 60 Å, less than or about 40 Å, less than or about 20 Å, or less. At reduced thicknesses, such as less than 10 Å, the seed layer 320 may not be thick enough to increase adhesion between the substrate 305 or layer of material 310 on the substrate 305 and the subsequently formed metal hardmask. At increased thicknesses greater than 500 Å, the seed layer 320 may require too much time for formation and provide no greater benefit than a thickness of less than or about 500 Å.

Additionally, an increased thickness of the seed layer 320 may impact subsequent etch performance.

By performing the surface treatment at optional operations 205-215 and/or forming the seed layer 320 at optional operations 220-230, hardmask material subsequently deposited may better adhere to the substrate 305 or layer of material 310 on the substrate 305. More specifically, metal-containing material in the hardmask material may better bond and adhere to the terminations 315 of dangling bonds or other ligand terminations at the surface of the substrate 305 provided by the surface treatment and/or to the seed layer 320 than to the substrate 305 or layer of material 310 on the substrate 305 directly.

Therefore, after the surface treatment at optional operations 205-215 and/or the seed layer 320 deposition at optional operations 220-230, method 200 may include providing deposition precursors to the processing region at operation 235. Plasma effluents of the deposition precursors may be formed at optional operation 240. At operation 245, the substrate 305 may be contacted with the plasma effluents of the deposition precursors. As illustrated in FIG. 3D, the contacting may deposit a metal-containing hardmask 325 on the substrate 305 at operation 245.

The deposition precursors may include a metal-containing precursor. The deposition precursors may include a single metal precursor, a mixed-metal precursor, or a combination of multiple metal precursors. In embodiments, the deposition precursors may be or include a chromium-containing precursor, a cobalt-containing precursor, a hafnium-containing precursor, a molybdenum-containing precursor, an osmium-containing precursor, a ruthenium-containing precursor, a rhenium-containing precursor, a tantalum-containing precursor, a titanium-containing precursor, a tungsten-containing precursor, or a zirconium-containing precursor. The metal-containing precursors may be any metal precursors used or useful in semiconductor processing. For example, the metal-containing precursors may be metal fluorides, metal chlorides, metal carbonyls, or any other metal-containing materials.

The deposition precursors may also include one or more of a boron-containing precursor, a carbon-containing precursor, a nitrogen-containing precursor, and a silicon-containing precursor. Similar to the seed layer precursors, an exemplary boron-containing precursor may be diborane (B₂H₆), and exemplary nitrogen-containing precursors may be ammonia (NH₃) or nitrous oxide (N₂O), and an exemplary silicon-containing-containing precursors may be silane (SiH₄) or disilane (Si₂H₆). Exemplary carbon-containing precursors may be a hydrocarbon, such as propene (C₃H₆). Any other boron-containing precursor, carbon-containing precursor, nitrogen-containing precursor, and silicon-containing precursor used or useful in semiconductor processing may additionally or alternatively be provided to deposit the seed layer 320 on the surface of the substrate 305. Similar to the treatment precursor and/or seed layer precursor, one or more carrier or inert gases may be provided to the processing region with the deposition precursors. For example, argon, helium, xenon, or any other inert gas may be provided with the deposition precursors.

The plasma effluents of the deposition precursors may be formed at a plasma power of greater than or about 200 W, and may be formed at greater than or about 250 W, greater than or about 500 W, greater than or about 750 W, greater than or about 1,000 W, greater than or about 1,250 W, greater than or about 1,500 W, greater than or about 1,750 W, greater than or about 2,000 W, greater than or about 2,250 W, or greater. Increased plasma powers for forming plasma effluents of the deposition precursors may increase deposition rate as well as metal incorporation in the hardmask material 325.

While depositing the metal-containing hardmask material 325 on the substrate 305, method 200 may include increasing a flow rate of the metal-containing precursor while contacting the substrate 305 with the plasma effluents of the deposition precursors and/or increasing a plasma power while contacting the substrate 305 with the plasma effluents of the deposition precursors. By ramping up the flow rate of the metal-containing precursor and/or plasma power, adhesion to the substrate 305 or the layer of material 310 on the substrate 305 may be increased. During the ramping up phase, the concentration of non-metal-containing material in the metal-containing hardmask material 325 may be increased relative to a bulk portion of the metal-containing hardmask material 325. The reduced concentration in metal-containing material may allow for better adherence, such as between the boron, carbon, nitrogen, and/or silicon in the metal-containing hardmask material 325 and the substrate 305 or the layer of material 310 on the substrate 305.

In embodiments, an initial flow rate of the metal-containing precursor may be 0 sccm. During a first period of time, which may be referred to as the ramping phase, the flow rate of the metal-containing precursor may be gradually increased, such as from a first time set point to a second time set point. Similarly, an initial plasma power may be relatively low, such as less than or about 500 W. During the ramping phase, the plasma power may be increased to a plasma power used during the deposition of the bulk portion of the metal-containing hardmask material 325, such as any of the plasma powers previously discussed. During deposition of the bulk portion of the metal-containing hardmask material 325, process conditions may remain constant. For example, the flow rate of the metal-containing precursor and/or the plasma power may be increased during the ramping phase, but the flow rate of the metal-containing precursor and/or the plasma power may be constant during deposition of the bulk portion of the metal-containing hardmask material 325.

The first period of time may be a portion of a total deposition duration. In embodiments, the first period of time may be less than or about 20% of a total deposition duration, and may be less than or about 18% of a total deposition duration, less than or about 16% of a total deposition duration, less than or about 15% of a total deposition duration, less than or about 14% of a total deposition duration, less than or about 13% of a total deposition duration, less than or about 12% of a total deposition duration, less than or about 11% of a total deposition duration, less than or about 10% of a total deposition duration, or less.

It is noted that the term “ramping” as used herein means gradually increasing a process parameter from the first time set point to the second time set point over a predetermined time-period with a desired ramp-up rate. The term “ramp-up” used herein is not a sudden change caused by an action of a throttle or other valve opening and closing.

Depending on the deposition precursors used, the metal-containing hardmask may include one or more of chromium, cobalt, hafnium, molybdenum, osmium, ruthenium, rhenium, tantalum, titanium, tungsten, and zirconium. An amount of metal in the metal-containing hardmask 325 may be greater than or about 10 at. %, and may be greater than or about 12 at. %, greater than or about 13 at. %, greater than or about 14 at. %, greater than or about 15 at. %, greater than or about 16 at. %, greater than or about 17 at. %, greater than or about 18 at. %, greater than or about 19 at. %, greater than or about 20 at. %, greater than or about 21 at. %, greater than or about 22 at. %, greater than or about 23 at. %, greater than or about 24 at. %, greater than or about 25 at. %, greater than or about 26 at. %, greater than or about 27 at. %, greater than or about 28 at. %, greater than or about 29 at. %, greater than or about 30 at. %, or higher.

Operation 245 may be continued for a sufficient amount of time to form the metal-containing hardmask material 325 to a desired thickness. The desired thickness of the metal-containing hardmask material 325 may depend on, at least in part, a thickness and etch resistance of the material to be etched relative to the metal-containing hardmask material 325. In embodiments, a thickness of the metal-containing hardmask material 325 may be greater than or about 50 Å, and may be greater than or about 100 Å, greater than or about 250 Å, greater than or about 500 Å, greater than or about 750 Å, greater than or about 1,000 Å, greater than or about 5,000 Å, greater than or about 10,000 Å, greater than or about 50,000 Å, or more. Additionally, the thickness of the metal-containing hardmask material 325 may be less than or about 50,000 Å, and may be less than or about 10,000 Å, less than or about 5,000 Å, less than or about 1,000 Å, less than or about 750 Å, less than or about 500 Å, less than or about 250 Å, less than or about 100 Å, or less.

Process conditions may impact the operations performed in method 200. Each of the operations of method 200 may be performed during a constant temperature in embodiments, while in some embodiments the temperature may be adjusted during different operations. In embodiments of the present technology, method 200 may be performed at substrate, pedestal, and/or chamber temperatures less or about 600° C., which may be due to thermal budget issues, and may be performed at temperatures less than or about 575° C., less than or about 550° C., less than or about 525° C., less than or about 500° C., less than or about 475° C., less than or about 450° C., less than or about 425° C., less than or about 400° C., less than or about 375° C., less than or about 350° C., less than or about 325° C., less than or about 300° C., less than or about 275° C., less than or about 250° C., less than or about 225° C., less than or about 200° C., or lower. The temperature may also be maintained at any temperature within these ranges, within smaller ranges encompassed by these ranges, or between any of these ranges.

The pressure within the semiconductor processing chamber may also affect the operations performed. Each of the operations of method 200 may be performed during a constant pressure in embodiments, while in some embodiments the pressure may be adjusted during different operations. In embodiments of the present technology, method 200 may be performed at chamber pressures less than about 10 Torr. Accordingly, the pressure may be maintained at less than or about 8 Torr, less than or about 6 Torr, less than or about 4 Torr, less than or about 2 Torr, less than or about 1 Torr, less than or about 750 mTorr, less than or about 500 mTorr, less than or about 250 mTorr, less than or about 100 mTorr, less than or about 80 mTorr, less than or about 60 mTorr, less than or about 40 mTorr, less than or about 20 mTorr, less than or about 15 mTorr, or less. The pressure may also be maintained at any pressure within these ranges, within smaller ranges encompassed by these ranges, or between any of these ranges.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursor, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a treatment precursor to a processing region of a semiconductor processing chamber, wherein a substrate is disposed within the processing region;
contacting a surface of the substrate with the treatment precursor;
providing deposition precursors to the processing region, wherein the deposition precursors comprise a metal-containing precursor;
forming plasma effluents of the deposition precursors; and
contacting the substrate with the plasma effluents of the deposition precursors, wherein the contacting deposits a metal-containing hardmask on the substrate.

2. The semiconductor processing method of claim 1, wherein the treatment precursor comprises a hydrogen-containing precursor, a nitrogen-containing precursor, or a hydrogen-and-nitrogen-containing precursor.

3. The semiconductor processing method of claim 1, further comprising:
forming plasma effluents of the treatment precursor.

4. The semiconductor processing method of claim 3, wherein the plasma effluents of the treatment precursor are formed at a plasma power of less than or about 1,000 W.

5. The semiconductor processing method of claim 1, further comprising:
prior to providing the deposition precursors, providing a seed layer precursor to the processing region; and
contacting the substrate with the seed layer precursor, wherein the contacting deposits a seed layer on the substrate, and wherein the metal-containing hardmask is deposited on the seed layer.

6. The semiconductor processing method of claim 5, wherein the seed layer precursor comprises one or more of a boron-containing precursor, a nitrogen-containing precursor, and a silicon-containing precursor.

7. The semiconductor processing method of claim 5, further comprising:
forming plasma effluents of the seed layer precursor.

8. The semiconductor processing method of claim 1, wherein the metal-containing hardmask comprises one or more of chromium, cobalt, hafnium, molybdenum, osmium, ruthenium, rhenium, tantalum, titanium, tungsten, and zirconium.

9. A semiconductor processing method comprising:
providing a seed layer precursor to a processing region of a semiconductor processing chamber, wherein a substrate is disposed within the processing region;
contacting the substrate with the seed layer precursor, wherein the contacting 4 deposits a seed layer on the substrate; providing deposition precursors to the processing region, wherein the deposition precursors comprise a metal-containing precursor;
forming plasma effluents of the deposition precursors; and
contacting the substrate with the plasma effluents of the deposition precursors, wherein the contacting deposits a metal-containing hardmask on the substrate.

10. The semiconductor processing method of claim 9, wherein the seed layer consists of boron, nitrogen, oxygen, silicon, or a combination thereof.

11. The semiconductor processing method of claim 10, further comprising:
forming plasma effluents of the seed layer precursor.

12. The semiconductor processing method of claim 11, wherein the plasma effluents of the seed layer precursor are formed at a plasma power of less than or about 2,250 W.

13. The semiconductor processing method of claim 9, wherein the substrate comprises a layer of silicon-containing material or a layer of carbon-containing material.

14. The semiconductor processing method of claim 9, further comprising:
increasing a flow rate of the metal-containing precursor while contacting the substrate with the plasma effluents of the deposition precursors;
increasing a plasma power while contacting the substrate with the plasma effluents of the deposition precursors; or
both.

15. A semiconductor processing method comprising:
providing deposition precursors to a processing region of a semiconductor processing chamber, wherein a substrate is disposed within the processing region, and wherein the deposition precursors comprise a metal-containing precursor;
forming plasma effluents of the deposition precursors; and
contacting the substrate with the plasma effluents of the deposition precursors, wherein the contacting deposits a metal-containing hardmask on the substrate, wherein a flow rate of at least one of the deposition precursors, a plasma power, or both are increased during a first amount of deposition of the metal-containing hardmask.

16. The semiconductor processing method of claim 15, further comprising, prior to providing the deposition precursors:
contacting a surface of the substrate with a treatment precursor;
contacting the surface of the substrate with a seed layer precursor, wherein the contacting deposits a seed layer on the substrate; or
both.

17. The semiconductor processing method of claim 15, wherein the first amount of deposition is less than or about 10% of a total deposition duration.

18. The semiconductor processing method of claim 15, wherein the metal-containing precursor comprises a chromium-containing precursor, a cobalt-containing precursor, a hafnium-containing precursor, a molybdenum-containing precursor, an osmium-containing precursor, a ruthenium-containing precursor, a rhenium-containing precursor, a tantalum-containing precursor, a titanium-containing precursor, a tungsten-containing precursor, or a zirconium-containing precursor.

19. The semiconductor processing method of claim 15, wherein the deposition precursors further comprise one or more of a boron-containing precursor, a carbon-containing precursor, a nitrogen-containing precursor, and a silicon-containing precursor.

20. The semiconductor processing method of claim 15, wherein a temperature in the processing region is maintained at less than or about 600° C.
